(19) United States
(12) Patent Application Publication
(10) Pub. No.: US 2007/0132034 A1
(43) Pub. Date: Jun. 14, 2007

(54) Isolation body for semiconductor devices and method to form the same

(76) Inventors: Giuseppe Curello, Portland, OR (US); Mark Bohr, Aloha, OR (US); Hemant V. Deshpande, Beaverton, OR (US); Sunit Tyagi, Portland, OR (US)

Correspondence Address: INTEL/BLAKELY, 12400 WILSHIRE BOULEVARD, SEVENTH FLOOR, LOS ANGELES, CA, 90025-1030, US

(21) Appl. No.: 11/304,016

(22) Filed: Dec. 14, 2005

(51) Int. Cl. H01L 29/76

(52) U.S. Cl. 257/374

(57) ABSTRACT

A semiconductor device and method for its fabrication are described. An isolation body may be formed prior to formation of an active region. In one embodiment, the isolation body is void-free.

### BACKGROUND OF THE INVENTION

1) Field of the Invention

The invention is in the field of Semiconductor Devices.

2) Description of Related Art

For the past several decades, integrated circuits containing semiconductor devices, such as Metal Oxide Semiconductor Field-Effect Transistors (MOS-FETs), have been fabricated on bulk silicon substrates. Often, there is a requirement to isolate individual or groups of semiconductor devices from one another on a single bulk silicon substrate in order to avoid cross-talk between such devices within an integrated circuit. Accordingly, isolation bodies are typically formed within a bulk silicon substrate. Active regions formed in the silicon substrate are isolated from one another by the isolation bodies.

As scaling of integrated circuits fabricated on silicon substrates continues, real estate optimization of the silicon substrate surface becomes increasingly important. Solutions for optimizing the use of the silicon substrate include increasing the density of the semiconductor devices in an integrated circuit as well as shrinking the dimensions of the components of these devices, including shrinking the dimensions of the isolation bodies. Currently, a fabrication technique known as shallow-trench-isolation (STI), involving the creation of a pattern of etched-out trenches within the bulk silicon substrate and subsequent filling of the trenches with an insulating material, is used to achieve electrical isolation between individual or groups of semiconductor devices. In the STI process, there is a trade-off between how deep (increased electrical isolation) and how narrow (higher packing density) the isolation bodies can be formed. If trenches are too deep and narrow, the filling process can often lead to the formation of voids in the isolation body, significantly degrading the electrical isolation ability of the isolation body.

FIGS. 1A-F illustrate a typical process for forming an isolation body in a bulk silicon substrate. Referring to FIG. 1A, the top surface 102 of a silicon substrate 100 is masked with a desired pattern by masking layer 103. A dry etch process is used to create a trench 104 in the portions of silicon substrate 100 that are not protected by masking layer 103, forming patterned silicon substrate 101, as shown in FIG. 1B. An insulating material layer 105 is then deposited above the structure formed in FIG. 1B, filling trench 104. For deep and narrow trenches, a void 106 can form in the insulating material layer 105 as it fills and pinches off in the trench 104, as depicted in FIG. 1C. A planarization step is often used to confine the insulating material layer 105 to trench 104, forming an isolation body 107, as shown in FIG. 1D. Referring to FIG. 1E, typical processing involves the removal of masking layer 103 from the structure formed in FIG. 1D. Thus, a patterned silicon substrate 101 with an isolation body 107 formed therein is fabricated. As depicted in FIG. 1E, the STI process illustrated in FIGS. 1A-E is amenable to the formation of a void 106 within the isolation body 107. Subsequent processing steps may lead to the recessing of isolation body 107 to form recessed isolation body 117, as depicted in FIG. 1F. The recessing may open void 106 to form cavity 116, resulting in an isolation body 117 that can trap unwanted materials, e.g. silicide films, in cavity 116. Thus, a method to form isolation bodies free from voids is described herein.

### BRIEF DESCRIPTION OF THE DRAWINGS

FIGS. 1A-F illustrate cross-sectional views representing the formation of an isolation body, depicting a void in the isolation body, in accordance with the prior art.

FIG. 2 illustrates a cross-sectional view of two MOS-FET devices including void-free isolation bodies, in accordance with an embodiment of the present invention.

FIGS. 3A-J illustrate cross-sectional views representing the formation of void-free isolation bodies, in accordance with an embodiment of the present invention.

FIGS. 4A-B illustrate cross-sectional views representing the formation of void-free isolation bodies with reverse taper profiles, in accordance with an embodiment of the present invention.

FIG. 5 illustrates a cross-sectional view of two MOS-FET devices including void-free isolation bodies with reverse taper profiles, in accordance with an embodiment of the present invention.

FIGS. 6A-B illustrate cross-sectional views representing the formation of void-free, multi-layer stack isolation bodies, in accordance with an embodiment of the present invention.

FIG. 7 illustrates a cross-sectional view of two MOS-FET devices including void-free, multi-layer stack isolation bodies, in accordance with an embodiment of the present invention.

FIGS. 8A-B illustrate cross-sectional views representing the formation of void-free isolation bodies with footed profiles, in accordance with an embodiment of the present invention.

FIG. 9 illustrates a cross-sectional view of two MOS-FET devices including void-free isolation bodies with footed profiles, in accordance with an embodiment of the present invention.

FIG. 10 illustrates a cross-sectional view of two MOS-FET devices including void-free isolation bodies with a retained mask layer, in accordance with an embodiment of the present invention.

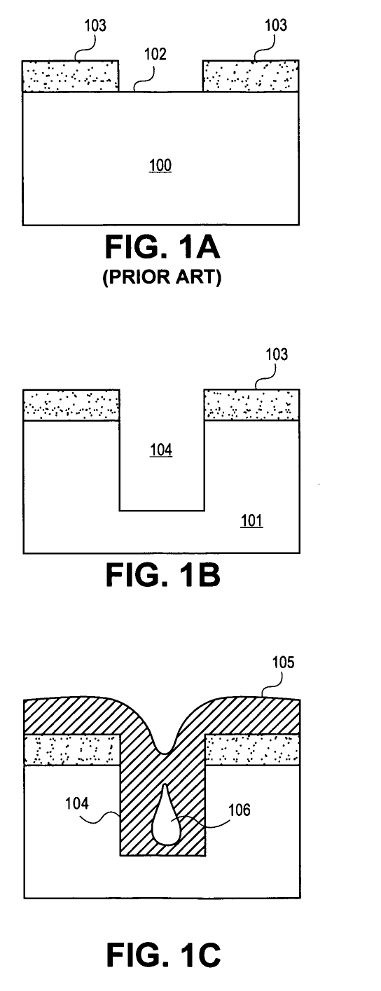

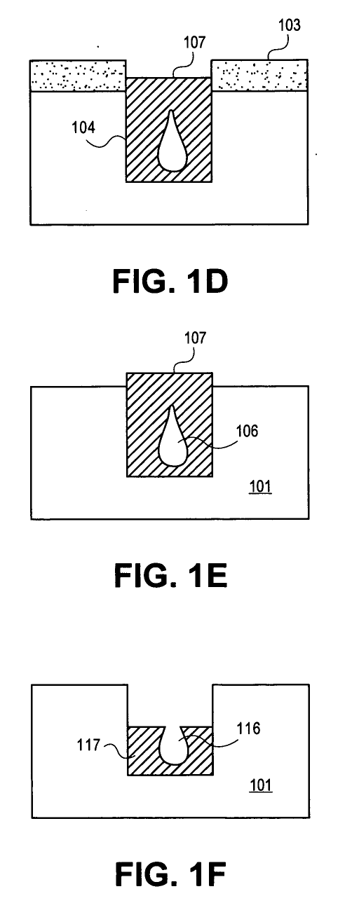

### DETAILED DESCRIPTION

A process for fabricating semiconductor devices and the resultant devices are described. In the following description, numerous specific details are set forth, such as specific dimensions and processing regimes, in order to provide a thorough understanding of the present invention. It will be apparent to one skilled in the art that the present invention may be practiced without these specific details. In other instances, well-known processing steps are not described in detail, in order to not unnecessarily obscure the present invention. Furthermore, it is understood that the various embodiments shown in the figures are illustrative representations and are not necessarily drawn to scale.

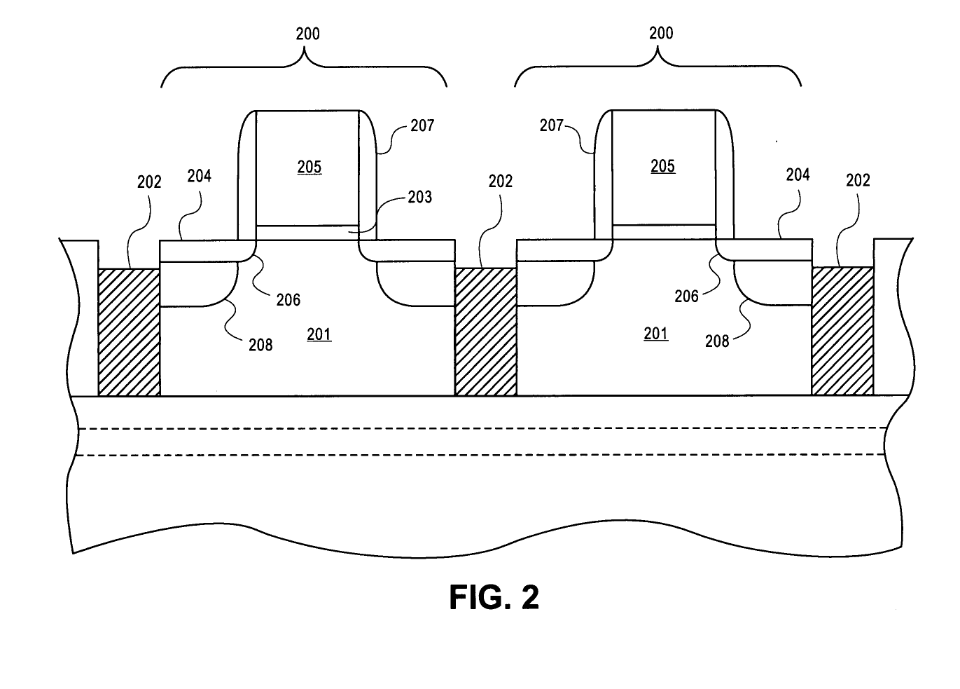

Disclosed herein is an isolation body and is a method to form such a body. Distinct from etching and subsequently filling trenches in a semiconductor substrate, as described above in the STI process, the isolation body described herein may be formed as a stand alone feature above a semiconductor substrate prior to the formation of an active region on the same semiconductor substrate. An insulating material layer may first be deposited above the entire surface of a semiconductor substrate. A masking layer may then be patterned above the insulating material layer. Finally, a pattern may be etched into the insulating material layer to form an isolation body or an array of isolation bodies. In accordance with an embodiment of the present invention, the top surface of the semiconductor substrate is exposed where isolation bodies have not been formed. The exposed top surface of the semiconductor substrate may provide a foundation for the growth of an active region. The active region may subsequently provide a surface for further fabrication of a semiconductor device. The isolation bodies may separate active regions, and hence may separate the semiconductor devices subsequently formed. Referring to FIG. 2, in accordance with an embodiment of the present invention, MOS-FETs 200 are formed above active regions 201 and separated by isolation bodies 202.

A process of first forming a stand alone isolation body by patterning an insulating material layer may reduce or eliminate the formation of voids within the isolation body, as depicted in FIG. 2. The elimination of voids within isolation bodies used to separate individual or groups of semiconductor devices may provide an improved electrical isolation of such individual or groups of semiconductor devices. Also, smaller dimensions may be attainable for an insulating body formed by first patterning an insulating material as compared to the dimensions attainable for an isolation body formed by the STI process, which are limited by the fill technique employed. Furthermore, a process of forming an isolation body prior to defining the active region onto which a semiconductor device is fabricated may permit a larger selection of materials used to form the active region. Active region materials that are sensitive to or easily damaged by the STI process may be used in conjunction with an embodiment of the present invention wherein the isolation body is formed before the active region material is grown.

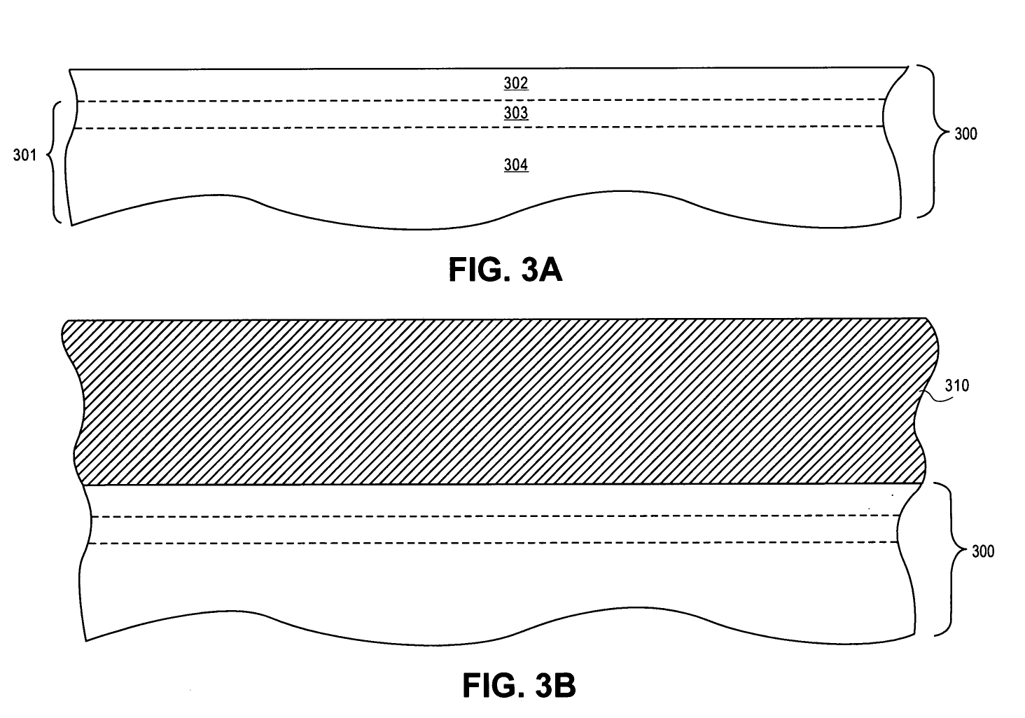

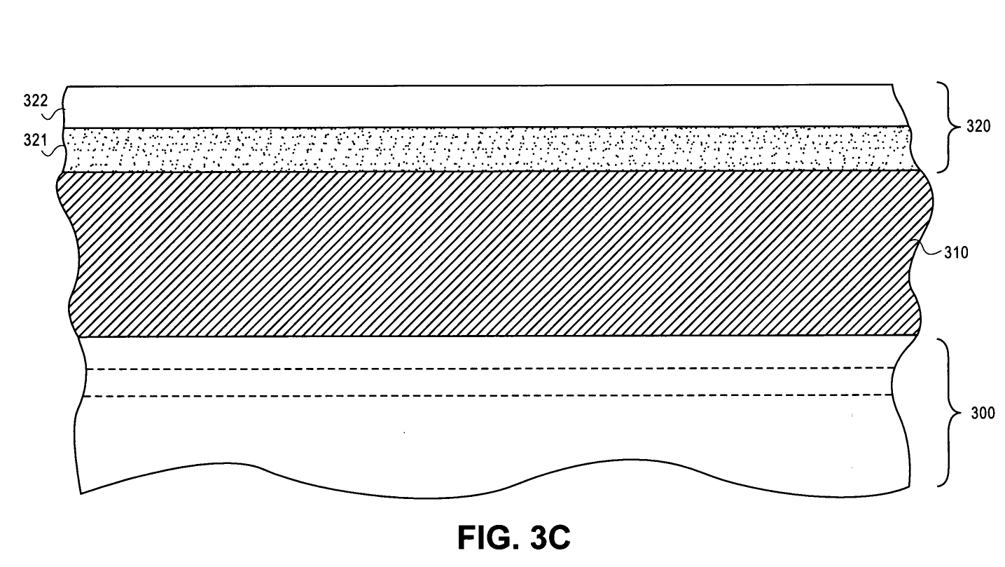

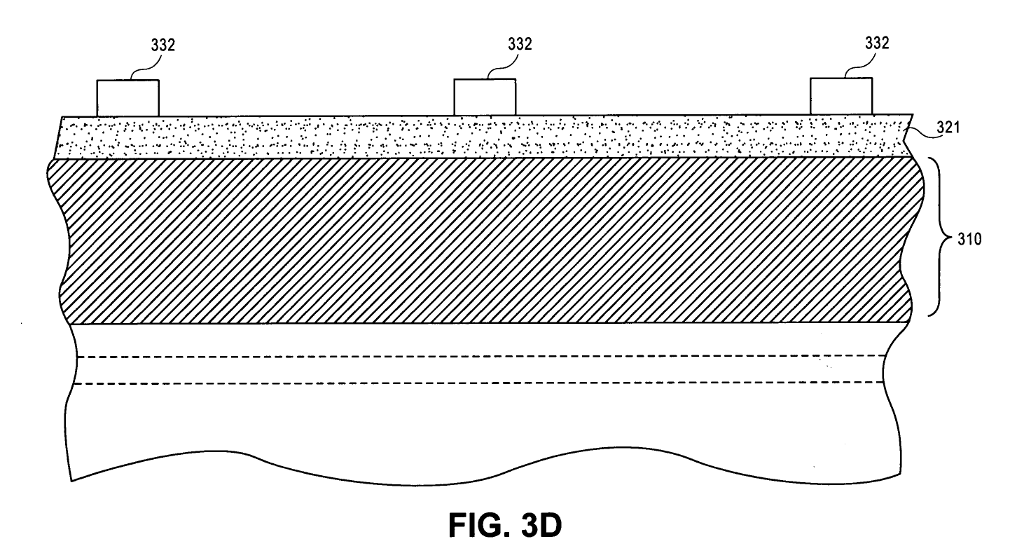

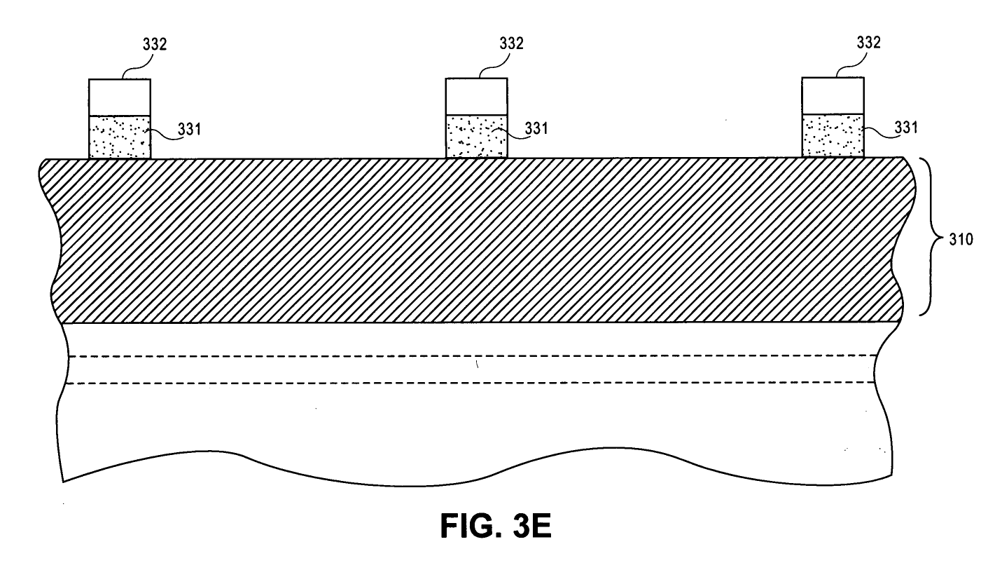

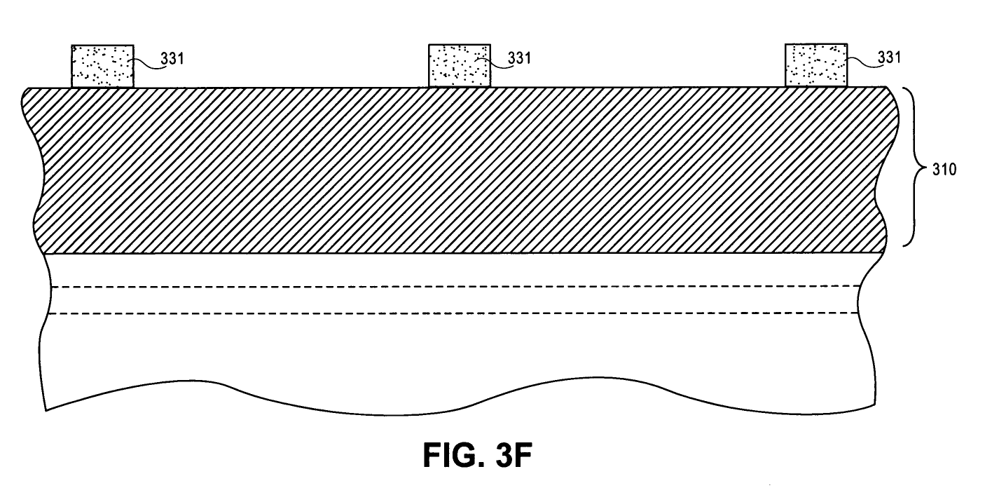

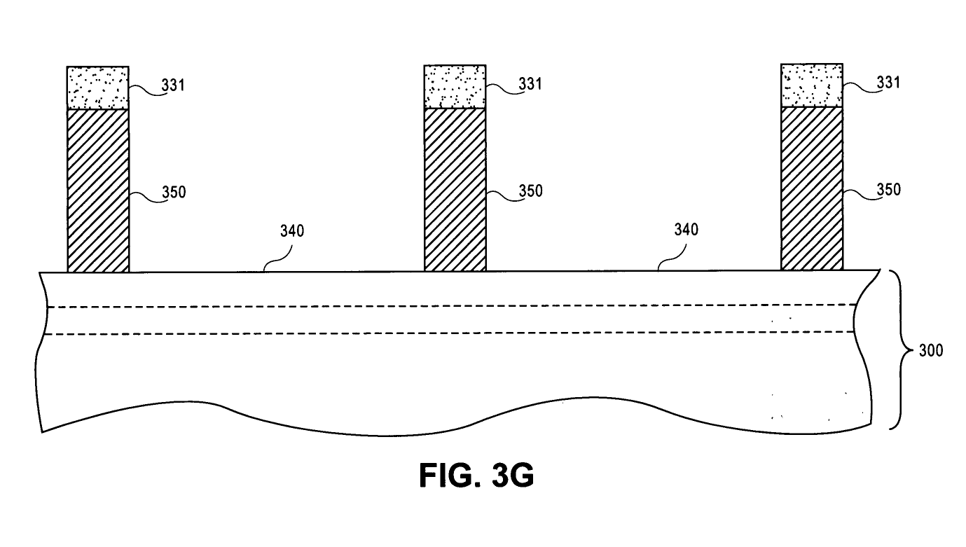

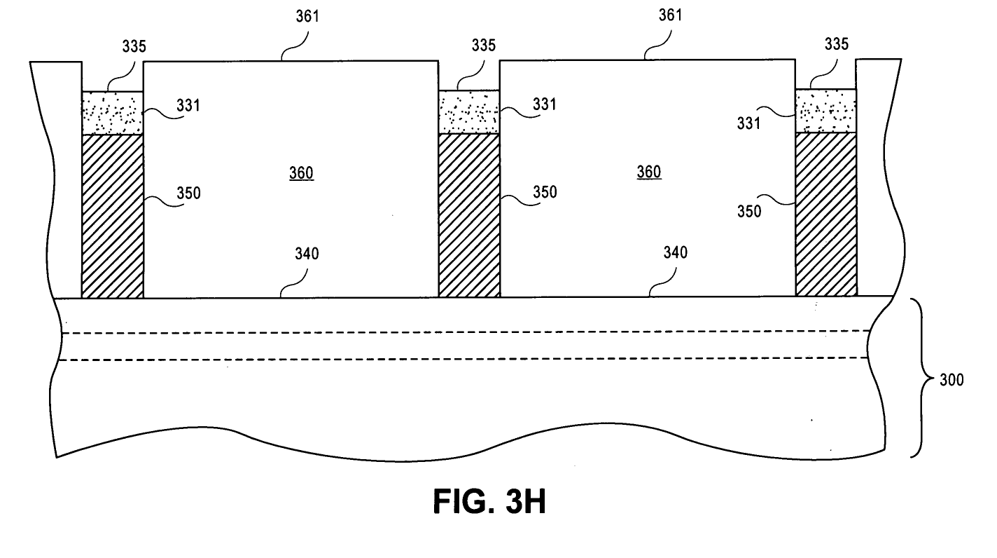

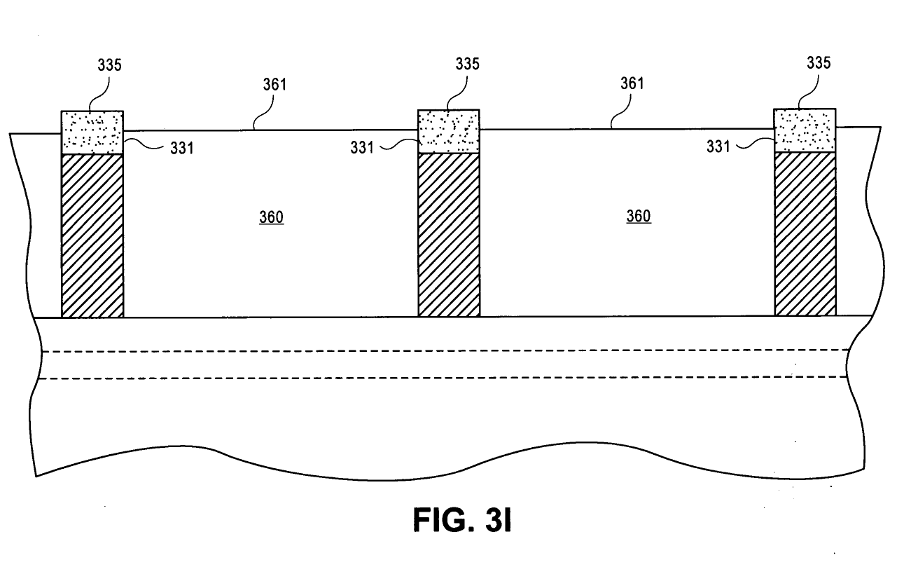

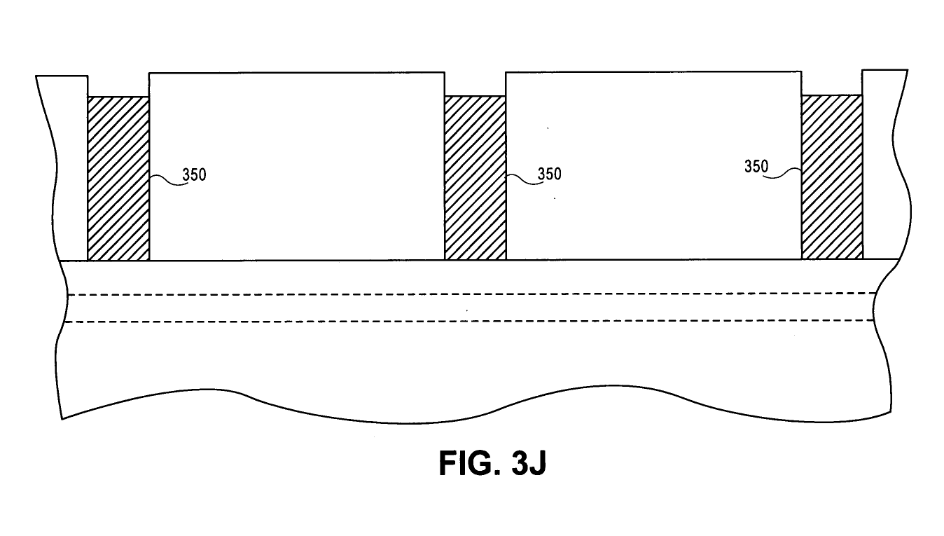

A surface for fabricating semiconductor devices may be provided by first forming a pattern of isolation bodies above a semiconductor substrate and next growing an active region material above exposed portions of the semiconductor substrate not blocked by the formed isolation bodies. In accordance with an embodiment of the present invention, FIGS. 3A-J illustrate the initial formation of isolation bodies and subsequent formation of active regions. In one embodiment, a platform onto which semiconductor devices are formed is thus provided.

Referring to FIG. 3A, semiconductor substrate 300 may be comprised of any material suitable for semiconductor fabrication. In one embodiment, semiconductor substrate 300 is a bulk substrate comprised of a single crystal of silicon, germanium, silicon/germanium or a III-V compound semiconductor material. In another embodiment, semiconductor substrate 300 is comprised of a bulk layer 301 with a top epitaxial layer 302. Bulk layer 301 may be comprised of a single crystal of silicon, germanium, silicon/germanium, a III-V compound semiconductor material or quartz. Top epitaxial layer 302 may be comprised of a single crystal layer of silicon, germanium, silicon/germanium or a III-V compound semiconductor material. In another embodiment, semiconductor substrate 300 is comprised of a top epitaxial layer 302 on a middle insulating layer 303 which is above a lower bulk layer 304. Top epitaxial layer 302 may be comprised of a single crystal layer of silicon [e.g. to form a silicon-on-insulator (SOI) semiconductor substrate], germanium, silicon/germanium or a III-V compound semiconductor material. Insulating material layer 303 may be comprised of any insulating material suitable for semiconductor fabrication, such as silicon dioxide, silicon nitride, silicon oxynitride, a high-k dielectric layer (e.g. a layer of hafnium oxide or zirconium oxide) or a stack of layers thereof. Lower bulk layer 304 may be comprised of a single crystal of silicon, germanium, silicon/germanium, a III-V compound semiconductor material or quartz.

Referring to FIG. 3B, an insulating material layer 310 may be deposited on semiconductor substrate 300 by any suitable technique. Insulating material layer 310 may be used to form an isolation body with a height substantially equal to the thickness of insulating material layer 310. Insulating material layer 310 may be of a thickness to provide an isolation body height sufficient to electrically isolate individual or groups of semiconductor devices. In one embodiment, insulating material layer 310 has a thickness in the range of 50-2000 nanometers. In another embodiment, insulating material layer 310 has a thickness in the range of 200-400 nanometers. In an embodiment, insulating material layer is comprised of an insulating material such as but not limited to silicon dioxide, silicon nitride, silicon oxynitride, a high-k dielectric layer or a multi-layer stack thereof. In accordance with an embodiment of the present invention, portions of the top surface of semiconductor substrate 300 are exposed and active regions grown thereon, subsequent to the patterning of insulating material layer 310, as described below.

Insulating material layer 310 may then be patterned to form an isolation body or a patterned array of isolation bodies above semiconductor substrate 300. Referring to FIG. 3C, a masking layer 320 may be deposited above insulating material layer 310. Masking layer 320 may be comprised of any material suitable for forming a pattern above insulating material layer 310. In one embodiment, masking layer 320 is comprised of a negative or positive photo-resist. In another embodiment, masking layer 320 is a stacked layer comprised of a hard-mask material layer 321, such as but not limited to silicon dioxide, silicon nitride or silicon oxynitride, with an overlying photo-resist layer 322, as depicted in FIG. 3C.

Masking layer 320 may then be patterned by any suitable method, such as but not limited to a lithographic process. In one embodiment, layer 320 is patterned by conventional lithography, immersion lithography, extreme ultra-violet lithography or an imprint technique. In another embodiment, the limit of the lithographic process utilized defines the lower limit of the dimensions of the isolation body to be formed. In one embodiment, the width of lines of the mask formed is in the range of 20-1000 nanometers. In another embodiment, the width of lines of the mask formed is in the range of 50-200 nanometers. The resulting pattern may form a mask above a portion of insulating material layer 310 and may expose another portion of insulating material layer 310. In one embodiment, the mask is comprised of undeveloped photo-resist. In another embodiment, the mask is formed by patterning a photo-resist layer 322 to form photo-resist mask 332 above hard-mask material layer 321, as depicted in FIG. 3D. Hard-mask material layer 321 may then be etched to form hard-mask 331, as depicted in FIG. 3E. In one embodiment, photo-resist mask 332 is removed, leaving hard-mask 331, as depicted in FIG. 3F.

Referring to FIG. 3G, the exposed portions of insulating material layer 310 may be removed to expose surfaces 340 of semiconductor substrate 300 while the masked portions of insulating material layer 310 may be retained, forming isolation bodies 350. In one embodiment, exposed portions of insulating material layer 310 are removed by a dry etch process in alignment with hard-mask 331, such as but not limited to a plasma or an active ion dry etch process. In an embodiment, the dry etch gases comprise HBr, Cl₂, CF₄ or a combination thereof. In another embodiment, exposed portions of insulating material layer 310 are removed by an anisotropic etch process. Isolation bodies 350 may be formed with desired dimensions, as may be determined by the above masking process, and with a desired shape, as may be determined by the above removal process. In one embodiment of the present invention, isolation bodies 350 may have a height in the range of 50-2000 nanometers and a width in the range of 20-1000 nanometers. In another embodiment of the present invention, isolation bodies 350 may have a height in the range of 200-400 nanometers and a width in the range of 50-200 nanometers. In another embodiment, isolation bodies may have a height to width ratio of at least 3:1. In an embodiment of the present invention, the shape of the cross-section of isolation bodies 350 is substantially rectangular with nearly vertical sidewalls, as depicted in FIG. 3G. In another embodiment, isolation bodies 350 are void-free, also depicted in FIG. 3G. Hard-mask 331 may be removed at this stage, prior to any further processing steps.

Subsequent to the formation of the isolation bodies, as described above, active regions 360 may then be grown on the exposed surfaces 340 of semiconductor substrate 300, whereon the isolation bodies 350 do not reside, as illustrated in FIG. 3H. In an embodiment of the present invention, immediately prior to the growth of active regions 360, the exposed surfaces 340 of semiconductor substrate 300 are treated with surface termination treatment, such as but not limited an aqueous solution of hydrofluoric acid, ammonium fluoride, a combination thereof or a vapor comprising hydrogen fluoride. In another embodiment, the surface termination treatment renders exposed surfaces 340 of semiconductor substrate 300 hydrophilic or hydrophobic surfaces.

Active regions 360 may be grown by any suitable deposition or growth process and may comprise a semiconducting material. Active regions 360 may be grown to at least a thickness suitable to form a channel region in a semiconductor device, e.g. to form a channel region in a MOS-FET device. In one embodiment, active region 360 is grown to a thickness of at least the height of isolation bodies 350. In another embodiment, active region 360 is grown to a thickness between 200-400 nanometers. In one embodiment, active regions 360 are deposited by a chemical or a physical vapor deposition process. In another embodiment, active regions 360 are grown by an epitaxial process, such as but not limited to molecular beam epitaxy. In one embodiment, active regions 360 are formed by depositing or growing epitaxially a crystalline silicon, germanium or silicon/germanium layer. In another embodiment, active regions 360 are formed by growing epitaxially a III-V compound semiconductor material, such as but not limited to gallium nitride, gallium phosphide, gallium arsenide, indium phosphide, indium antimonide or multi-layer stacks thereof. Active regions 360 may be doped to a concentration sufficient to form a channel region in a semiconductor device, such as a channel region in a MOS-FET device. In one embodiment, active regions 360 are doped in situ or ion-implanted post-deposition with an appropriate dopant species, such as phosphorus, arsenic, boron, indium or a combination thereof. In another embodiment, active regions 360 are doped to a concentration in the range of 5×10¹⁴-5×10²⁰ atoms/cm³. In another embodiment, active regions 360 are doped to a concentration in the range of 1×10¹⁶-5×10¹⁸ atoms/cm³. In an embodiment, active regions 360 are comprised of lattice mismatch layers or a graded layer. Prior to any further processing steps, top surface 361 of active region 360 may be above top surface 335 of hard-mask 331, as depicted in FIG. 3H, top surface 361 of active region 360 may be flush with top surface 335 of hard-mask 331, or top surface 361 of active region 360 may be below top surface 335 of hard-mask 331.

Depending on the desired characteristics and desired surface smoothness of active regions 360, active regions 360 may be planarized by any suitable planarization method. In one embodiment, the planarization method is a chemical mechanical polish process step or a plasma etch-back. In one embodiment, active regions 360 are chemically-mechanically polished with top surface 335 of hard-mask 331 acting as a polish-stop. In accordance with one embodiment of the present invention, FIG. 3I illustrates the result of subjecting the structure in FIG. 3H to a chemical mechanical polish, wherein the polish rate of the active regions 360 is faster than the polish rate of the hard-mask 331 and top surface 361 of active regions 360 ends up below top surface 335 of hard-mask 331. In one embodiment, the root mean square surface roughness of top surfaces 361 of active regions 360 is in the range of 1-10 Angstroms.

Prior to any further processing steps, hard-mask 331 may be removed from isolation bodies 350 at this stage, as depicted in FIG. 3J. Hard-mask 331 may be removed by any suitable removal technique compatible with typical semiconductor fabrication conditions. In one embodiment of the present invention, hard-mask 331 is removed by a dry etch process, a wet chemical cleaning process or a combination thereof.

Upon completion of the fabrication of stand alone isolation bodies and subsequently grown active regions, formed above a semiconductor substrate, a semiconductor device may be fabricated above the active regions and isolated individually or in groups by the isolation bodies. In one embodiment, the semiconductor device is a MOS-FET, a bipolar transistor, a memory transistor or a micro-electronic machine (MEM). In another embodiment, the semiconductor device is a planar device or a non-planar device, such as a tri-gate or double-gate transistor. For illustrative purposes, MOS-FET devices are shown in FIG. 2 and are described below, in accordance with one embodiment of the present invention. As will be appreciated in the typical integrated circuit, both n- and p-channel transistors may be fabricated.

Referring again to FIG. 2, isolation bodies 202 may separate subsequently grown active regions 201 above which MOS-FETs 200 may be formed. In accordance with one embodiment of the present invention, isolation bodies 202 are void-free. A gate dielectric layer 203 may be formed above the top surface 204 of active region 201. In one embodiment, gate dielectric layer 203 is formed by a thermal oxidation process and is comprised of silicon dioxide or silicon oxynitride. In another embodiment, gate dielectric layer 203 is formed by chemical vapor deposition or atomic layer deposition and is comprised of a high-k dielectric layer such as but not limited to hafnium oxide, zirconium oxide, hafnium silicate, hafnium oxynitride or lanthanum oxide.

A gate electrode 205 may be formed above gate dielectric layer 203, as depicted in FIG. 2. Gate electrode 205 may be formed by a subtractive etching process scheme or a replacement gate process scheme. In one embodiment, gate electrode 205 is comprised of a polycrystalline silicon gate electrode, wherein the charge carriers are implanted during fabrication of the tip and source/drain regions described below. In another embodiment, gate electrode 205 is comprised of a metal layer such as but not limited to metal nitrides, metal carbides, hafnium, zirconium, titanium, tantalum, aluminum, ruthenium, palladium, platinum, cobalt, nickel or conductive metal oxides, e.g. ruthenium oxide. In one embodiment, a masking layer is retained above gate electrode 205.

A tip extension 206 may be formed by implanting charge carrier atoms into active region 201, as depicted in FIG. 2. Gate electrode 205 may act to mask a portion of active region 201, to form self-aligned tip extensions 206. In one embodiment, boron, arsenic, phosphorus, indium or a combination thereof is implanted into active region 201 to form tip extension 206.

Gate isolation spacers 207 may be formed by any suitable technique. In one embodiment, an insulating layer such as but not limited to silicon dioxide, silicon nitride, silicon oxynitride or carbon-doped silicon nitride is deposited by a chemical vapor deposition process, wherein the thickness of the insulating layer is selected to determine the final width of gate isolation spacer 207, and subsequently dry etched. In an embodiment, gate isolation spacer 207 forms a hermetic seal with gate electrode 205 and top surface 204 of active region 201 to encapsulate gate dielectric layer 203.

Source and drain regions 208 may be formed by implanting charge carrier atoms into active region 201. Gate isolation spacers 207 and gate electrode 205 may act to shield a portion of active region 201, forming self-aligned source/drain regions 208. In effect, the thickness of gate isolation spacer 207 may play a role in dictating the dimensions of source/drain region 208. In one embodiment, boron, arsenic, phosphorus, indium or a combination thereof is implanted into active region 201 to form source/drain region 208. MOS-FETs 200, depicted in FIG. 2, may then be integrated into an integrated circuit by conventional process steps, as known in the art.

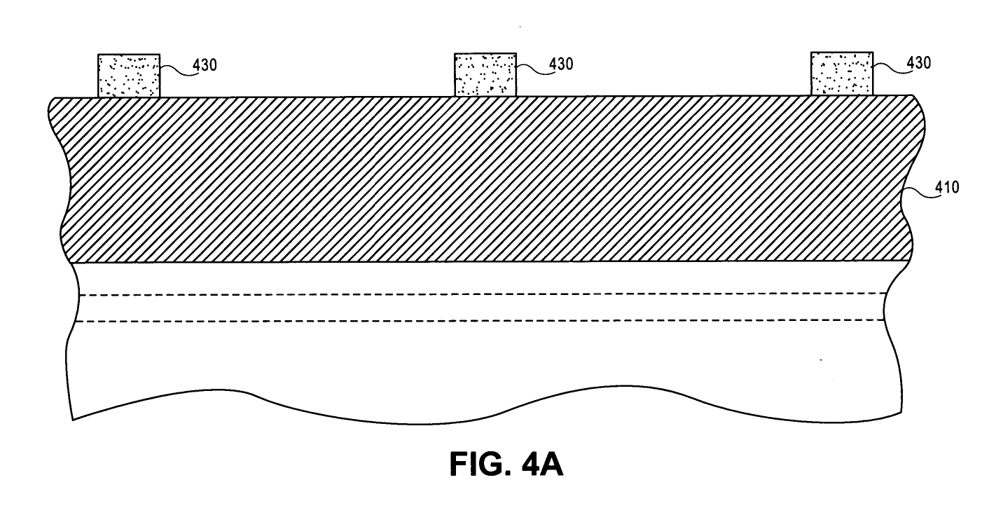

In another embodiment of the present invention, the isolation bodies may be formed with a reverse taper profile. By first fabricating the isolation bodies as stand alone elements with reverse taper features and then subsequently forming the active region areas, the risk of void formation may be eliminated. A method for fabricating isolation bodies 450 with reverse taper profiles is illustrated in the cross-sectional FIGS. 4A and 4B.

A mask 430 may be formed above a portion of insulating material layer 410, exposing another portion of insulating material layer 410, as depicted in FIG. 4A. Referring to FIG. 4B, the exposed portions of insulating material layer 410 may be removed in alignment with mask 430 to expose surfaces 440 of semiconductor substrate 400 while the masked portions of insulating material layer 410 may be retained, forming isolation bodies 450 with reverse taper profiles. Exposed portions of insulating material 410 may be removed by a dry etch process, such as but not limited to a plasma or an active ion dry etch process. In one embodiment, the dry etch process renders the reverse taper profiles, wherein the dry etchant is comprised of one of the gases HBr, Cl₂, CF₄ or a combination thereof. In another embodiment, a wet etch process renders the reverse taper profiles, wherein the wet etchant is comprised of an aqueous solution of hydrofluoric acid, ammonium fluoride or a combination thereof. In accordance with an embodiment of the present invention, isolation bodies 450 with reverse taper profiles have a height in the range of 50-2000 nanometers, a top width in the range of 20-1000 nanometers and a bottom width in the range of 50-1200 nanometers. In another embodiment of the present invention, isolation bodies 450 with reverse taper profiles have a height in the range of 200-400 nanometers, a top width in the range of 50-200 nanometers and a bottom width in the range of 100-400 nanometers. In another embodiment, isolation bodies 450 have a reverse taper profile angle θ formed by top surface 440 of semiconductor substrate 400 and the sidewall of isolation body 450 in the range of 45-89 degrees, as depicted in FIG. 4B. In another embodiment, isolation bodies 450 have a reverse taper profile angle θ in the range of 60-75 degrees. In another embodiment, isolation bodies 450 are void-free.

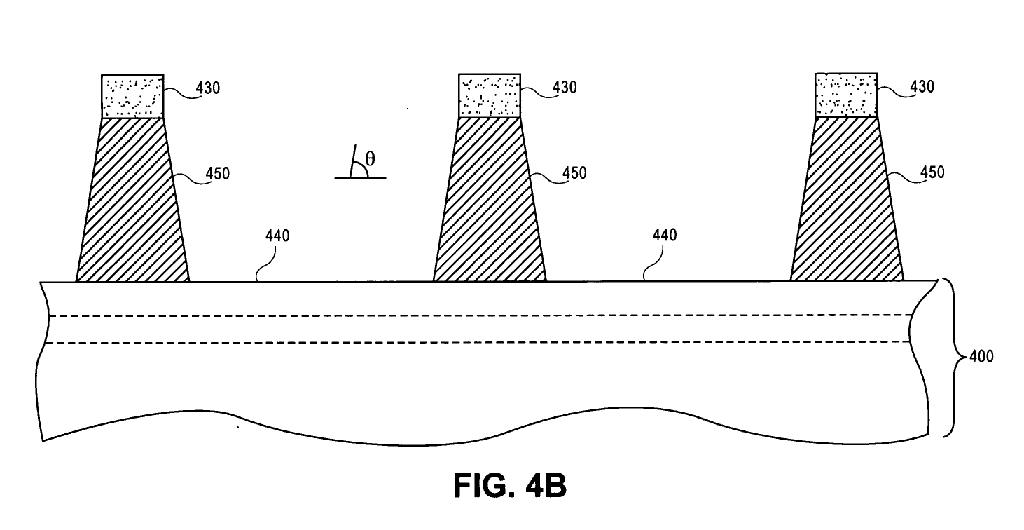

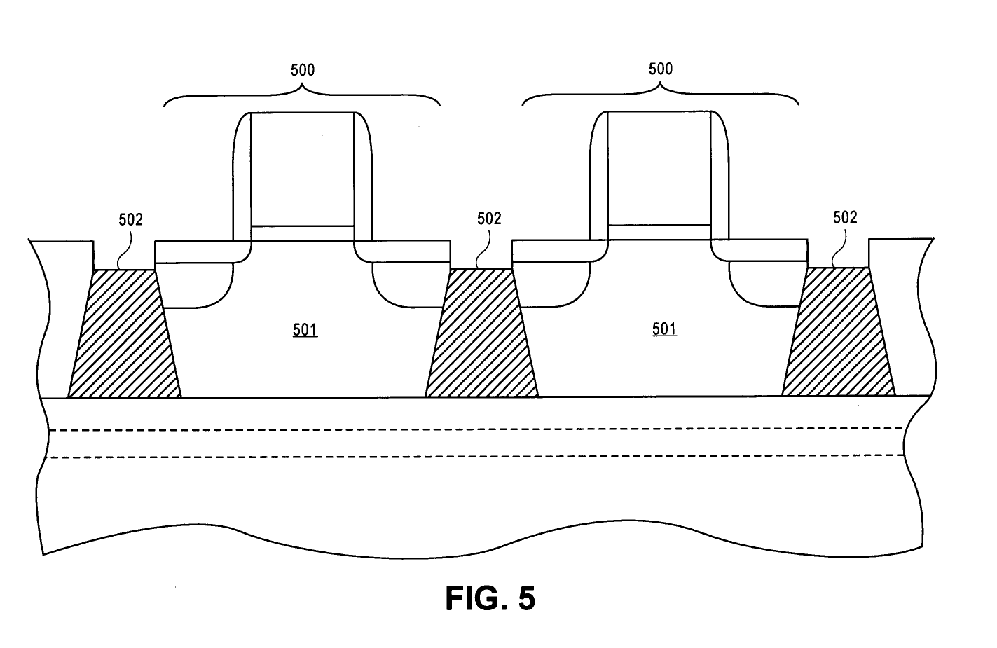

Subsequent to the formation of the isolation bodies 450 with reverse taper profiles, active regions may be grown on the exposed surfaces 450 of the semiconductor substrate 400, whereon the isolation bodies 450 do not reside. A semiconductor device may then be fabricated above the active regions and isolated individually or in groups by the isolation bodies 450 with reverse taper profiles. In one embodiment, the fabricated semiconductor device is a MOS-FET, a bipolar transistor, a memory transistor or a micro-electronic machine (MEM). In another embodiment, the semiconductor device is a planar device or a non-planar device, such as a tri-gate or double-gate transistor. For illustrative purposes, MOS-FET devices 500 fabricated on active regions 501 and isolated by isolation bodies 502 with reverse taper profiles are depicted in FIG. 5, in accordance with one embodiment of the present invention. As will be appreciated in the typical integrated circuit, both n- and p-channel transistors may be fabricated. MOS-FETs 500 may then be integrated into an integrated circuit by conventional process steps, as known in the art.

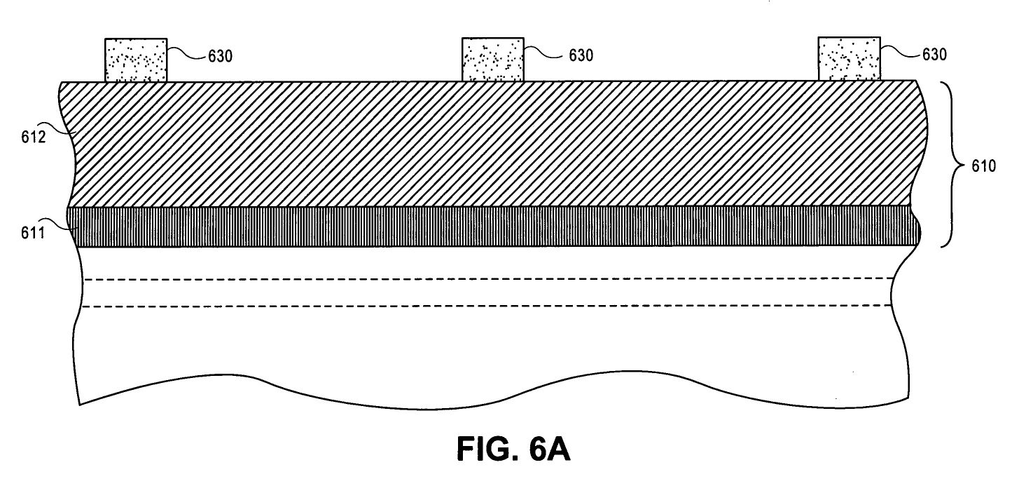

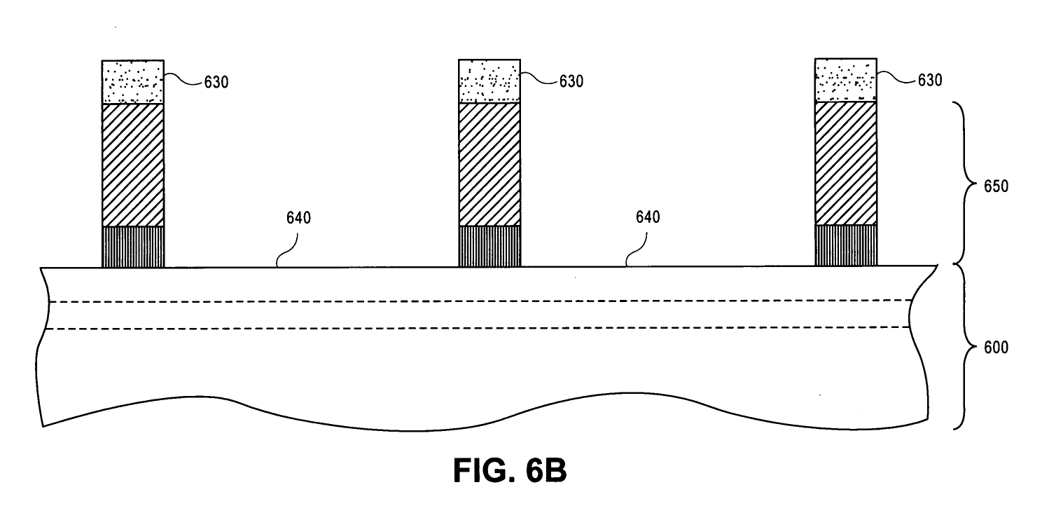

In another embodiment of the present invention, the isolation bodies may be formed with a multi-layer stack. By first fabricating the isolation bodies as stand alone elements and then subsequently forming the active region areas, formation of multi-layer stack isolation bodies may be possible. A method for fabricating multi-layer stack isolation bodies 650 is illustrated in the cross-sectional FIGS. 6A and 6B.

A mask 630 may be formed above a portion of insulating material layer 610, exposing another portion of insulating material layer 610, as depicted in FIG. 6A. In accordance with an embodiment of the present invention, insulating material layer 610 is comprised of at least two constituent layers 611 and 612 of insulating materials of differing composition. In one embodiment, constituent layer 611 is comprised of silicon dioxide and constituent layer 612 is comprised of silicon nitride or a high-k dielectric layer, such as but not limited to zirconium oxide or hafnium oxide. In another embodiment, constituent layer 612 is comprised of silicon dioxide and constituent layer 611 is comprised of silicon nitride or a high-k dielectric layer, such as but not limited to zirconium oxide or hafnium oxide.

Referring to FIG. 6B, the exposed portions of insulating material layer 610, comprised of constituent layers 611 and 612, may be removed in alignment with mask 630 to expose surfaces 640 of portions of semiconductor substrate 600 while the masked portions of insulating material layer 610 may be retained, forming multi-layer stack isolation bodies 650. In one embodiment, exposed portions of insulating material 610 are removed by a dry etch process, such as but not limited to a plasma or an active ion dry etch process. In accordance with an embodiment of the present invention, multi-layer stack isolation bodies 650 have a height in the range of 50-2000 nanometers and a width in the range of 20-1000 nanometers. In another embodiment of the present invention, multi-layer stack isolation bodies 650 have a height in the range of 200-400 nanometers and a width in the range of 50-200 nanometers. In an embodiment, the shape of the cross-section of multi-stack isolation body 650 is substantially rectangular with nearly vertical sidewalls, as depicted in FIG. 6B. In another embodiment, multi-layer stack isolation bodies have a reverse taper profile or a footed feature. In one embodiment, isolation bodies 650 are void-free.

Subsequent to the formation of the multi-layer stack isolation bodies 650, active regions may be grown on the exposed surfaces 640 of the semiconductor substrate 600, whereon the multi-layer stack isolation bodies 650 do not reside. A semiconductor device may then be fabricated above the active regions and isolated individually or in groups by multi-layer stack isolation body 650. In one embodiment, the fabricated semiconductor device is a MOS-FET, a bipolar transistor, a memory transistor or a micro-electronic machine (MEM). In another embodiment, the semiconductor device is a planar device or a non-planar device, such as a tri-gate or double-gate transistor. For illustrative purposes, MOS-FET devices 700 fabricated above active regions 701 and isolated by multi-layer stack isolation bodies 702 are depicted in FIG. 7, in accordance with one embodiment of the present invention. In one embodiment, isolation bodies 702 are comprised of layers 702A and 702B, also depicted in FIG. 7. As will be appreciated in the typical integrated circuit, both n- and p-channel transistors may be fabricated. MOS-FETs 700 may then be integrated into an integrated circuit by conventional process steps, as known in the art.

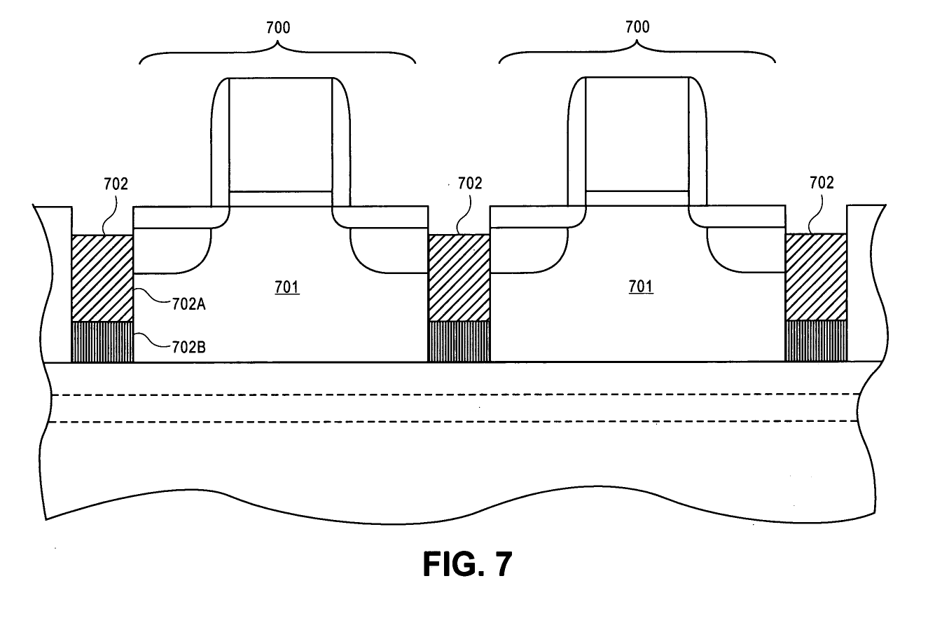

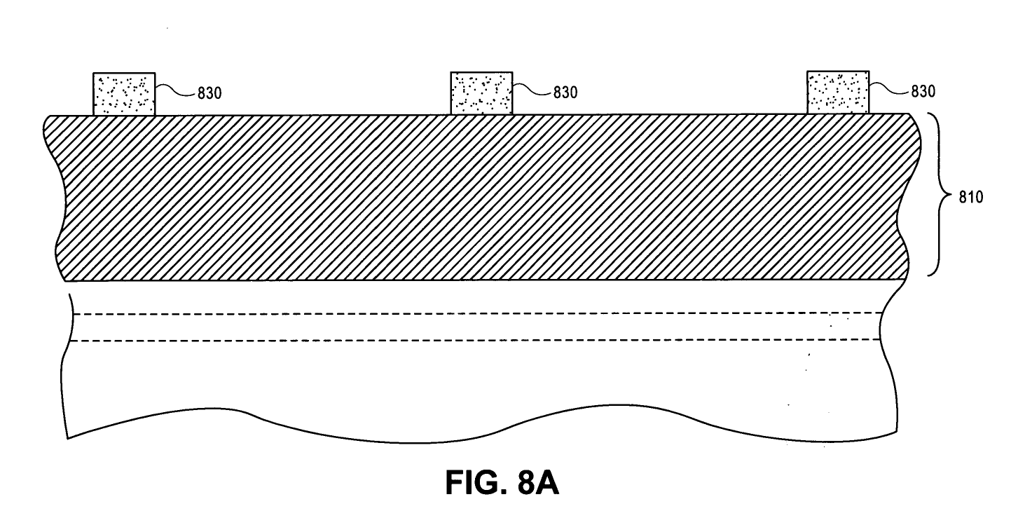

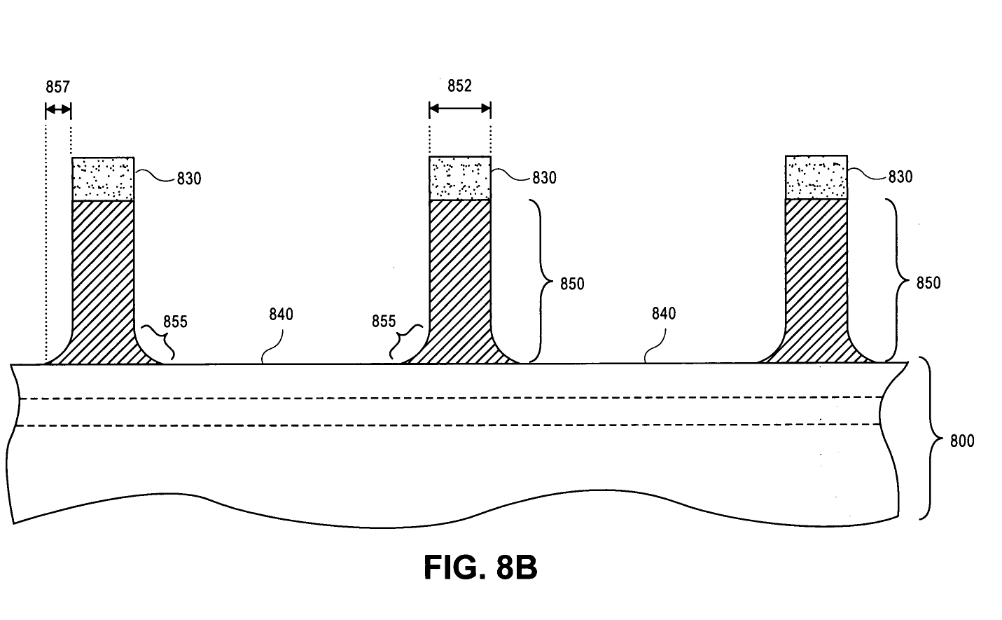

In another embodiment of the present invention, the isolation bodies may be formed with a footed feature. By first fabricating the isolation bodies as stand alone elements with footed features and then subsequently forming the active region areas, the risk of void formation may be eliminated. A method for fabricating isolation bodies 850 with footed features is illustrated in the cross-sectional FIGS. 8A and 8B.

A mask 830 may be formed above a portion of insulating material layer 810, exposing another portion of insulating material layer 810, as depicted in FIG. 8A. Referring to FIG. 8B, the exposed portions of insulating material layer 810 may be removed in alignment with mask 830 to expose surfaces 840 of semiconductor substrate 800 while the masked portions of insulating material layer 810 may be retained, forming isolation bodies 850 with footed features 855. Exposed portions of insulating material 810 may be removed by a dry etch process, such as but not limited to a plasma or an active ion dry etch process. In one embodiment, the dry etch process renders the footed feature, wherein the dry etchant is comprised of one of the gases HBr, Cl₂, CF₄ or a combination thereof. In another embodiment, a wet etch process renders the footed feature, wherein the wet etchant is comprised of an aqueous solution of hydrofluoric acid, ammonium fluoride or a combination thereof. In accordance with an embodiment of the present invention, isolation body 850 has a height in the range of 50-2000 nanometers, a body width 852 in the range of 20-1000 nanometers and a footed feature width 857 in the range of 1-50 nanometers. In another embodiment of the present invention, isolation body 850 has a height in the range of 200-400 nanometers, a body width 852 in the range of 50-200 nanometers and a footed feature width 857 in the range of 5-20 nanometers. In another embodiment, isolation bodies 850 with footed features 855 are void-free, as depicted in FIG. 8B.

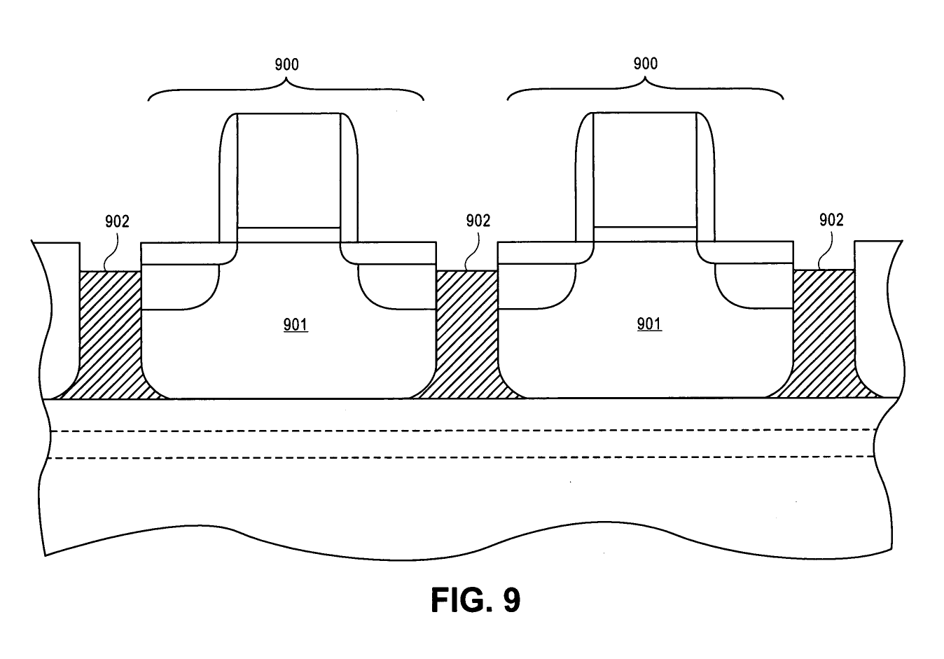

Subsequent to the formation of the isolation bodies 850 with footed features 855, active regions may be grown on the exposed surfaces 840 of semiconductor substrate 800, whereon the isolation bodies 850 do not reside. A semiconductor device may be fabricated above the active regions and isolated individually or in groups by isolation bodies 850 with footed profiles 855. In one embodiment, the semiconductor device is a MOS-FET, a bipolar transistor, a memory transistor or a micro-electronic machine (MEM). In another embodiment, the semiconductor device is a planar device or a non-planar device, such as a tri-gate or double-gate transistor. For illustrative purposes, MOS-FET devices 900 fabricated on active regions 901 and isolated by isolation bodies 902 with footed profiles are depicted in FIG. 9, in accordance with one embodiment of the present invention. As will be appreciated in the typical integrated circuit, both n- and p-channel transistors may be fabricated. MOS-FETs 900 may then be integrated into an integrated circuit by conventional process steps, as known in the art.

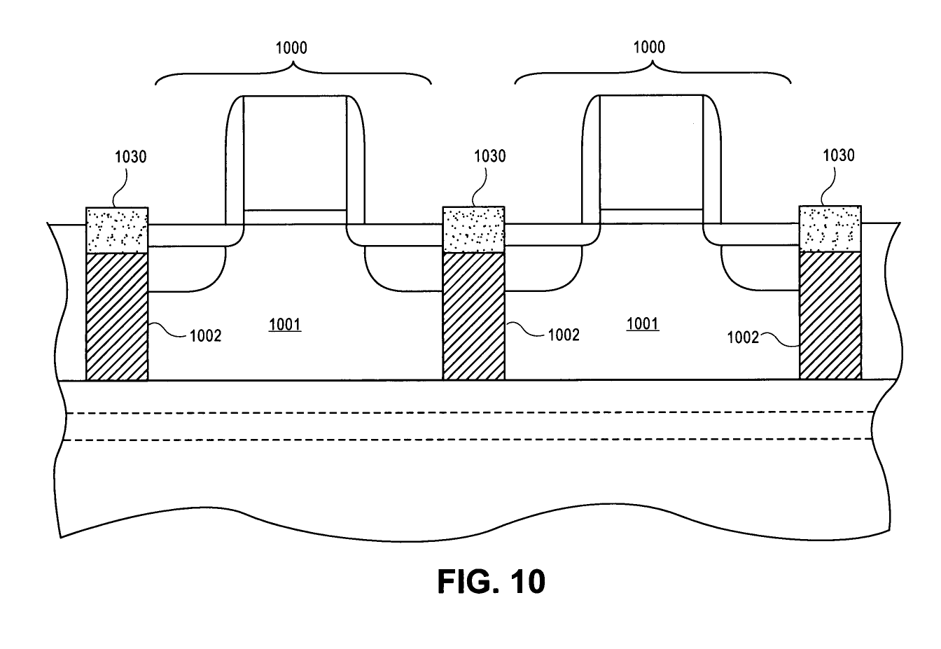

In another embodiment of the present invention, the masking layer used for patterning the isolation bodies may be retained. For illustrative purposes, MOS-FET devices 1000 fabricated above active regions 1001 and isolated by isolation bodies 1002 with a retained mask 1030 are depicted in FIG. 10, in accordance with one embodiment of the present invention. MOS-FETs 1000 may then be integrated into an integrated circuit by conventional process steps, as known in the art.

Thus, semiconductor devices incorporating isolation bodies and a method to form such devices and isolation bodies have been described. The isolation bodies may be void-free and may be formed first as stand alone features above a semiconductor substrate prior to the formation of active regions above the same semiconductor substrate. In one embodiment, the shape of the cross-section of the isolation body is substantially rectangular with nearly vertical sidewalls. In another embodiment, the shape of the cross-section of the isolation body has a taper profile. In another embodiment, the shape of the cross-section of the isolation body has a footed feature. In one embodiment, the isolation bodies are formed from a multi-layer stack of insulating materials. In another embodiment, a mask layer is retained above the isolation bodies. Improved electrical isolation of individual or groups of semiconductor devices is afforded by the elimination of voids within the isolation bodies, in accordance with an embodiment of the present invention. Also, smaller dimensions are attainable for insulating bodies formed by first patterning an insulating material, as described in conjunction with an embodiment of the present invention. Furthermore, a process of forming an isolation body prior to defining the active region above which a semiconductor device will be fabricated may permit a greater selection of materials used to form the active region.

What is claimed is:

1. A semiconductor device comprising:
an active region and an isolation body above a substrate, wherein said active region and said isolation body are adjacent, wherein said isolation body has a top width and a bottom width, and wherein said top width is smaller than said bottom width.

2. The device of claim 1, wherein said isolation body is void-free.

3. The device of claim 2, wherein said isolation body is comprised of an insulating layer selected from the group of silicon dioxide, silicon nitride, silicon oxynitride, a high-k dielectric layer or a multi-layer stack thereof.

4. The device of claim 3, wherein said isolation body has a reverse taper profile angle formed by a bottom surface of said isolation body and a sidewall of said isolation body and wherein said reverse taper profile angle is in the range of 45-89 degrees.

5. The device of claim 4 wherein said isolation body has a height in the range of 50-2000 nanometers and a top width in the range of 20-1000 nanometers.

6. The device of claim 5, wherein said active region is comprised of lattice mismatch layers or a graded layer.

7. The device of claim 3, wherein said isolation body has a footed feature.

8. The device of claim 7, wherein said isolation body with said footed feature has a height in the range of 50-2000 nanometers, a body width in the range of 20-1000 nanometers and a footed feature width in the range of 1-50 nanometers.

9. The device of claim 8, wherein said active region is comprised of lattice mismatch layers or a graded layer.

10. A method of forming a semiconductor device comprising:
forming an isolation body on a first region of a substrate; and
subsequent to forming said isolation body, forming an active region on a second portion of said substrate and adjacent to said isolation body.

11. The method of claim 7, wherein said isolation body is void-free.

12. The method of claim 8, wherein said isolation body is comprised of an insulating layer selected from the group of silicon dioxide, silicon nitride, silicon oxynitride, a high-k dielectric layer or a multi-layer stack thereof.

13. The method of claim 9, wherein, said isolation body has a substantially rectangular shape with a height in the range of 50-2000 nanometers and a width in the range of 20-1000 nanometers and a height to width ratio of at least 3:1.

14. The method of claim 9, wherein said active region is comprised of lattice mismatch layers or a graded layer.

15. The method of claim 11, wherein said substrate is comprised of a single crystal of silicon, germanium, silicon/germanium or a III-V compound semiconductor material.

16. A method of forming a semiconductor device comprising:
forming an active region and an isolation body on a substrate, wherein said isolation body is formed by depositing a dielectric layer on said substrate and patterning said dielectric layer to form an exposed portion of said substrate, and wherein said active region is subsequently formed by growing a semiconductor layer on said exposed portion of said substrate and adjacent to said isolation body;
forming a gate dielectric layer above said active region; and
forming a gate electrode above said gate dielectric layer.

17. The method of claim 13, wherein said isolation body has a reverse taper profile or a footed feature.

18. The method of claim 13, wherein said isolation body is comprised of an insulating layer selected from the group of silicon dioxide, silicon nitride, silicon oxynitride, a high-k dielectric layer or a multi-layer stack thereof.

19. The method of claim 15, wherein said gate dielectric layer is formed by chemical vapor deposition or atomic layer deposition and is comprised of a high-k dielectric layer selected from the group of hafnium oxide, zirconium oxide, hafnium silicate, hafnium oxynitride or lanthanum oxide.

20. The method of claim 16, wherein said gate electrode is comprised of a metal layer selected from the group of is comprised of a metal layer such as but not limited to metal nitrides, metal carbides, hafnium, zirconium, titanium, tantalum, aluminum, ruthenium, palladium, platinum, cobalt, nickel or conductive metal oxides.

21. The method of claim 15, wherein said active region is comprised of lattice mismatch layers or a graded layer.

22. The method of claim 18, wherein said gate dielectric layer is formed by chemical vapor deposition or atomic layer deposition and is comprised of a high-k dielectric layer selected from the group of hafnium oxide, zirconium oxide, hafnium silicate, hafnium oxynitride or lanthanum oxide.

23. The method of claim 19, wherein said gate electrode is comprised of a metal layer selected from the group of is comprised of a metal layer such as but not limited to metal nitrides, metal carbides, hafnium, zirconium, titanium, tantalum, aluminum, ruthenium, palladium, platinum, cobalt, nickel or conductive metal oxides.
